(19) United States
(12) Patent Application Publication
(10) Pub. No.: US 2016/0020606 A1
(43) Pub. Date: Jan. 21, 2016

(54) ELECTROSTATIC DISCHARGE PROTECTION CIRCUIT

(71) Applicant: KABUSHIKI KAISHA TOSHIBA, Tokyo (JP)

(72) Inventors: Kazuhiro KATO, Yokohama Kanagawa (JP); Takehito IKIMURA, Yokohama Kanagawa (JP)

(21) Appl. No.: 14/632,578

(22) Filed: Feb. 26, 2015

(30) Foreign Application Priority Data
Jul. 15, 2014 (JP) 2014-145445

(51) Int. Cl. H02H 9/04; H03K 17/22; H03K 19/20

(52) U.S. Cl. CPC H02H 9/041; H03K 19/20; H03K 17/22

(57) ABSTRACT

An electrostatic discharge protection circuit includes a first trigger circuit outputting a first trigger signal according to a first time constant and a voltage applied between power source lines. A second trigger circuit outputs a second trigger signal according to the voltage between the power source lines and a second time constant that is greater than the first time constant. A holding circuit outputs a shunt control signal in accordance with the first trigger signal and a reset signal supplied from a reset circuit in accordance with the second trigger signal. A shunt circuit is connected between the power source lines and provides a conductance path between the power source lines in accordance with the shunt control signal.

### CROSS-REFERENCE TO RELATED APPLICATION

This application is based upon and claims the benefit of priority from Japanese Patent Application No. 2014-145445, filed Jul. 15, 2014, the entire contents of which are incorporated herein by reference.

### FIELD

Embodiments described herein relate generally to an electrostatic discharge protection circuit.

### BACKGROUND

Electrostatic discharge (ESD) refers to electrical discharge from a charged person or machine to a semiconductor device, discharge from a charged semiconductor device to a ground potential, and the like. If a semiconductor device experiences ESD, a large current may be input into the semiconductor device from a terminal of the semiconductor device and a high voltage is generated in the semiconductor device due to the ESD charges. Thus, insulation breakdown of an internal element or unintended activation or operation of the semiconductor device is caused.

Various protection circuits have been proposed. There is a RC triggered (RCT) MOS circuit as a representative example of an electrostatic discharge protection circuit. The RCT MOS circuit has a configuration in which a trigger circuit including a resistor and a capacitor is connected in series between power source terminals drives a MOS transistor for discharge using a voltage at a connection node between the resistor and the capacitor as a trigger signal. Since an ON time of the MOS transistor for discharge is determined by a time constant of the trigger circuit, a time constant allowing an ESD surge to be sufficiently discharged is required. However, if the time constant is too large, the trigger circuit may be operated due to voltage fluctuation occurring during a rising time (startup) of the power source or oscillation of a power source voltage following an operation of an internal circuit and the MOS transistor for discharge may be operated (turned ON) even though an ESD surge has not occurred. When the MOS transistor for discharge is incorrectly operated (turned ON) during a rising time of the power source, the power source voltage may be increased insufficiently and operation of the internal circuit may fail or be improper. If the trigger circuit responds to oscillation of the power source voltage and the MOS transistor for discharge is turned ON too often or for too long a time, the discharge MOS transistor may be destroyed or impaired.

### DESCRIPTION OF THE DRAWINGS

FIG. 1 is a diagram illustrating an electrostatic discharge protection circuit according to a first embodiment.

FIG. 2 is a diagram illustrating an electrostatic discharge protection circuit according to a second embodiment.

FIG. 3 is a diagram illustrating an operation of the electrostatic discharge protection circuit according to the second embodiment.

FIG. 4 is a diagram illustrating an electrostatic discharge protection circuit according to a third embodiment.

### DETAILED DESCRIPTION

According to one embodiment, an electrostatic discharge protection circuit includes a first trigger circuit having a first time constant and configured to output a first trigger signal in accordance with the first time constant and a voltage applied between a first power source line and a second power source line. A second trigger circuit has a second time constant that is greater than the first time constant. The second trigger circuit is configured to output a second trigger signal in accordance with the second time constant and the voltage applied between the first power source line and the second power source line. A holding circuit is configured to output a shunt control signal in accordance with the first trigger signal and a reset signal output from a reset circuit that is configured to output the reset signal in accordance with the second trigger signal. A shunt circuit is connected between the first power source line and the second power source line. The shunt circuit provides a conductance path between the first and second power source lines in accordance with the shunt control signal.

In general, according to another embodiment, an electrostatic discharge protection circuit includes a first power source line and a second power source line. The protection circuit includes a first trigger circuit and a second trigger circuit, in which the first trigger circuit has a first time constant and outputs a first trigger signal in accordance with a voltage applied between the first power source line and the second power source line, and the second trigger circuit has a second time constant greater than the first time constant and outputs a second trigger signal in accordance with a voltage applied between the first power source line and the second power source line. The protection circuit includes a holding circuit that is in a holding state in accordance with the first trigger signal. The protection circuit includes a reset circuit that resets the holding state of the holding circuit in accordance with the second trigger signal. The protection circuit includes a shunt circuit that is connected between the first power source line and the second power source line and is controlled to be turned on or off by a signal from the holding circuit.

Electrostatic discharge protection circuits according to example embodiments will be described in detail with reference to the accompanying drawings. However, this disclosure is not limited to these example embodiments.

### First Embodiment

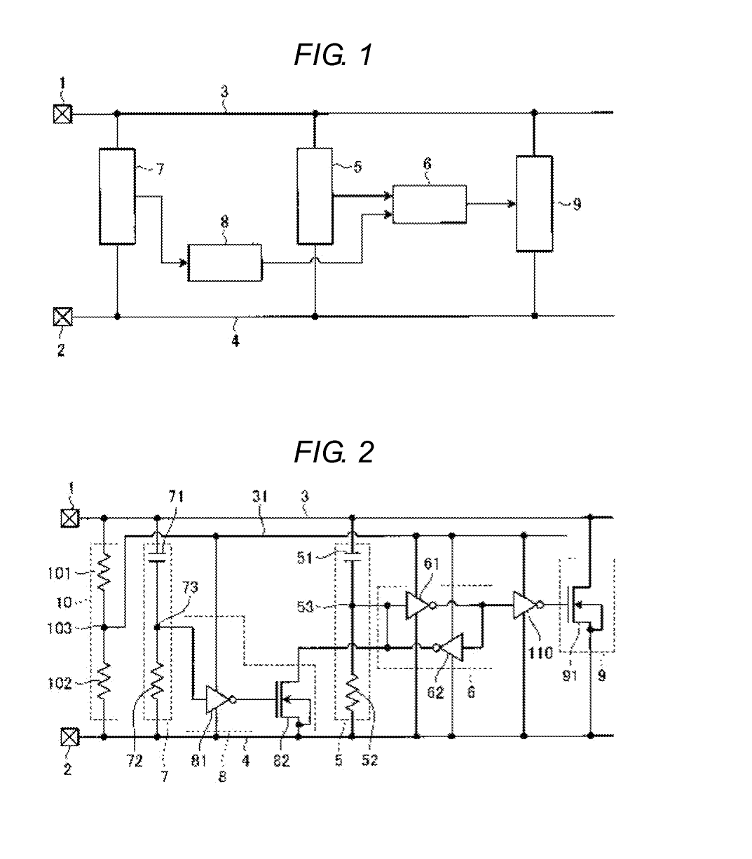

FIG. 1 is a diagram illustrating an electrostatic discharge protection circuit according to a first embodiment. The electrostatic discharge protection circuit according to this first embodiment includes a first power source terminal 1 and a second power source terminal 2. A first power source line 3 is connected to the first power source terminal 1. A second power source line 4 is connected to the second power source terminal 2. An internal circuit (not specifically illustrated) is connectable between the first power source line 3 and the second power source line 4, but a description of the internal circuit will be omitted and, in general, the other details of the internal circuit may vary according to intended end use.

A first trigger circuit 5 with a first time constant τ1 is connected between the first power source line 3 and the second power source line 4. The first trigger circuit 5 outputs a first trigger signal in accordance with a power source voltage applied between the first power source line 3 and the second power source line 4. The time constant τ1 is set to a value in a range from 2 ns (nanosecond) to 10 ns, which corresponds, for example, to a rising time of an ESD surge in a human body model (HBM) commonly used in the standards for ESD testing.

The first trigger circuit 5 is connected to a holding circuit 6. The holding circuit 6 holds a signal level of the first trigger signal. A holding state of the holding circuit 6 is reset by a reset signal from a reset circuit 8 after a predetermined time.

A second trigger circuit 7 with a second time constant τ2 is connected between the first power source line 3 and the second power source line 4. The second trigger circuit 7 outputs a second trigger signal in accordance with the power source voltage applied between the first power source line 3 and the second power source line 4. The second time constant τ2 is set to a value greater than the first time constant τ1. The second time constant τ2 is set to a value in which the standards of ESD testing are considered, for example. In an ESD human body model (HBM: human body model), a test of discharging charges stored in a capacitor of 100 pF (pico-farad) through a resistor of 1.5 KΩ (kilo-ohm) is performed. For this reason, the second time constant τ2 is set to 1 μs (micro-second), which is a value of six to seven times 150 ns which corresponds to a value of a time constant of 150 ns obtained through a capacitor of 100 pF and a resistor of 1.5 kΩ, which are defined in the standards of ESD testing. This value of the second time constant τ2 is to allow discharging of the ESD surge sufficiently. The second trigger signal is supplied to the reset circuit 8.

A shunt circuit 9 is connected between the first power source line 3 and the second power source line 4. An output signal of the holding circuit 6 is supplied to the shunt circuit 9. That is, turning on or off of the shunt circuit 9 is controlled by the output signal of the holding circuit 6. Therefore, shunt circuit 9 is controlled by the output signal of holding circuit 6 to open or close an electrical connection between first power source line 3 and second power source line 4.

An ESD protection operation according to this first embodiment is performed as follows. If a positive ESD surge, with respect to the second power source terminal 2, is applied to the first power source terminal 1 and a rising time of the ESD surge is shorter than the first time constant τ1, the first trigger circuit 5 outputs the first trigger signal. The holding circuit 6 holds a signal level (for example, H level) of the first trigger signal in accordance with the first trigger signal. An output signal of the H level from the holding circuit 6 causes the shunt circuit 9 to turn on and the ESD surge is discharged via the shunt circuit 9.

The second time constant τ2 is a value greater than the first time constant τ1. The second trigger circuit 7 outputs the second trigger signal in accordance with the applied ESD surge and the second time constant τ2.

If a signal level of the second trigger signal decreases and reaches a predetermined threshold according to the second time constant τ2, the reset circuit 8 outputs a reset signal. The reset signal causes the holding state of the holding circuit 6 to be reset. Accordingly, the output signal of the holding circuit 6 is reset and thus the shunt circuit 9 turns off. That is, the second trigger circuit 7 may adjust a time for which the shunt circuit 9 is in an ON state. For example, a configuration may be made in which the ESD surge may be discharged sufficiently by setting the second time constant τ2 to 1 μs, which is six to seven times as great as the time constant of 150 ns defined according to the standards of ESD testing.

The first trigger circuit 5 is not operated when a power source voltage fluctuates with a rising time longer than the first time constant τ1. For this reason, a signal for causing the shunt circuit 9 to turn on is not supplied from the holding circuit 6. Accordingly, a range of a rising time of a power source voltage in which the electrostatic discharge protection circuit is not operated may be set by using the first time constant τ1.

According to this first embodiment, a range of operating the electrostatic discharge protection circuit in response to fluctuations of the power source voltage may be set according to a time constant of the first trigger circuit 5, that is, the first time constant τ1. Accordingly, a rising time of power source voltage for operating the electrostatic discharge protection circuit may be set by using the first time constant τ1. For example, a configuration may be made in which the first time constant τ1 is set to a value in a range from 2 ns to 10 ns as defined as a rising time of a surge in the human body model (HBM) of the standards of ESD testing and the electrostatic discharge protection circuit is operated based on the set first time constant τ1. Since the first trigger circuit 5 is not operated when a power source voltage having a rising time longer than this first time constant τ1, that is, a power source voltage having slowly rising fluctuations, it is possible to limit an operation range of the electrostatic discharge protection circuit by setting the first time constant τ1. A timing after which the shunt circuit 9 is caused to turn off after an ESD-type triggering event may be set according to a time constant of the second trigger circuit 7, that is, the second time constant τ2. Accordingly, a configuration in which an ESD surge may be discharged sufficiently by setting the second time constant τ2 may be made. A configuration may be made in which a range of fluctuation in power source voltage, which is for operating the electrostatic discharge protection circuit is limited by setting the first time constant τ1 to be a short time constant for responding to the ESD surge and the ESD surge is sufficiently discharged via the shunt circuit 9 by setting the second time constant τ2 of the second trigger circuit 7 to be large. The shunt circuit 9 may maintain the ON state until the holding circuit 6 is reset by the reset signal from the reset circuit 8 (which is controlled by the second trigger circuit 7) even though the first time constant τ1 is set to be small. In addition, a holding time of the holding circuit 6 may be adjusted by the second time constant τ2. Accordingly, it is possible to provide an electrostatic discharge protection circuit capable of suppressing an incorrect operation and discharging an ESD surge sufficiently by setting the first time constant τ1 and the second time constant τ2.

### Second Embodiment

FIG. 2 is a diagram illustrating a configuration of an electrostatic discharge protection circuit according to a second embodiment. Components corresponding to those in the first embodiment are denoted by the same reference numerals and the descriptions will be repeated only as necessary. In this second embodiment, the first trigger circuit 5 is configured with a CR circuit including a series circuit of a capacitor 51 and a resistor 52 connected in series. The capacitor 51 and the resistor 52 are connected to a common connection node 53. The first time constant τ1 of the first trigger circuit 5 is set to a value in a range from 2 ns to ns, for example, by using the respective values of capacitance and resistance of the capacitor 51 and the resistor 52.

The holding circuit 6 comprises a latch circuit including a first inverter 61 and a second inverter 62. An input end of the first inverter 61 is connected to the common connection node 53 of the first trigger circuit 5. An input end of the second inverter 62 is connected to an output end of the first inverter 61. An output end of the second inverter 62 is connected to the input end of the first inverter 61. That is, an output from the first trigger circuit 5 is supplied to the input end of the first inverter 61 and an output from the first inverter 61 is supplied to the input end of the second inverter 62. An output of the second inverter 62 is supplied to the input end of the first inverter 61.

The second trigger circuit 7 is configured with a CR circuit including a series circuit of a capacitor 71 and a resistor 72 connected in series. The capacitor 71 and the resistor 72 are connected to a common connection node 73. The second time constant τ2 of the second trigger circuit 7 is set to 1 μs, for example, by using the respective values of capacitance and resistance of the capacitor 71 and the resistor 72.

The reset circuit 8 includes an inverter 81 and an n-type metal-oxide-semiconductor (NMOS) transistor 82. The common connection node 73 of the second trigger circuit 7 is connected to an input end of the inverter 81. An output end of the inverter 81 is connected to a gate (control) electrode of the NMOS transistor 82. A source electrode of the NMOS transistor 82 is connected to the second power source line 4. A drain electrode of the NMOS transistor 82 is connected to the input end of the holding circuit 6. A reset signal is output from the drain electrode.

An output of the holding circuit 6 is supplied through an inverter 110 to a gate electrode of an NMOS transistor (an NMOS shunt transistor) 91 in the shunt circuit 9. A source electrode of the NMOS shunt transistor 91 is connected to the second power source line 4 and a drain electrode of the NMOS shunt transistor 91 is connected to the first power source line 3.

In this second embodiment, a bias circuit 10 is connected between the first power source line 3 and the second power source line 4. The bias circuit 10 includes a series circuit of a first resistor 101 and a second resistor 102 connected in series. A bias voltage which is resistor-divided by the first resistor 101 and the second resistor 102 is output from a common connection node 103 and supplied to a power source line 31. A voltage at the common connection node 103 is used as a bias voltage of each of the inverter 81 of the reset circuit 8, the inverters 61 and 62 of the holding circuit 6, and the inverter 110. The inverter 81 of the reset circuit 8, the inverters 61 and 62 of the holding circuit 6, and the inverter 110 may incorporate circuit elements having a low breakdown voltage by using the power source voltage voltage-divided by the bias circuit 10 as the bias voltage.

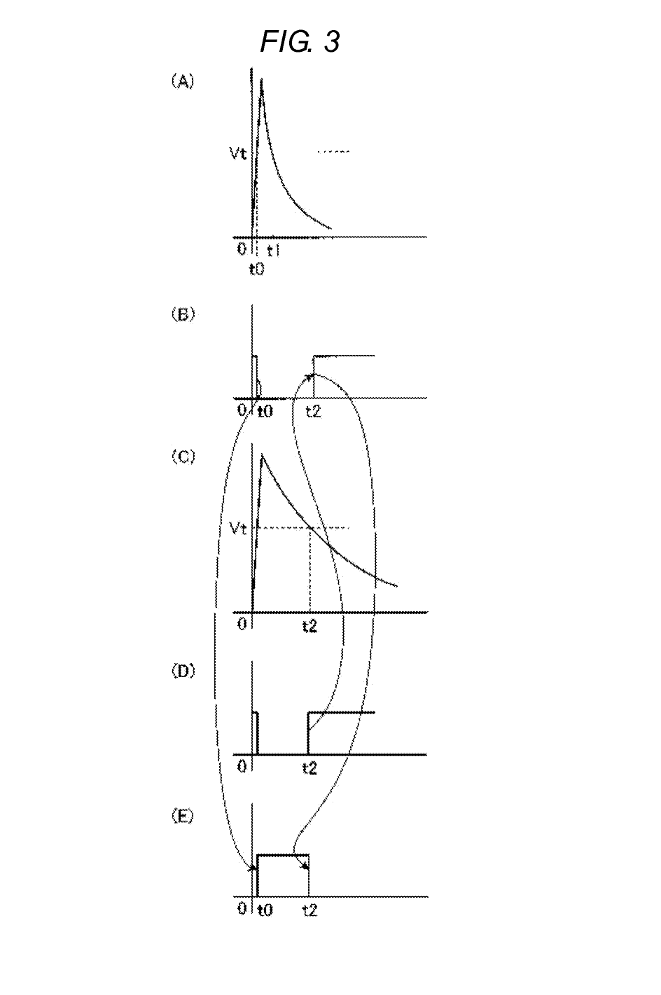

An operation of the electrostatic discharge protection circuit according to the second embodiment illustrated in FIG. 2 will be described using FIG. 3. Part (A) of FIG. 3 illustrates an output of the first trigger signal. Part (B) of FIG. 3 illustrates an output of the holding circuit 6. Part (C) of FIG. 3 illustrates an output of the second trigger signal. Part (D) of FIG. 3 illustrates an output of the reset circuit 8. Part (E) of FIG. 3 illustrates an output of the inverter 110. When an ESD surge is applied, the first trigger circuit 5 is operated to output a first trigger signal (part (A) of FIG. 3). The output of the inverter 61 of the holding circuit 6 becomes an L level at a timing t0 at which a signal level of the first trigger signal increases exceeding a circuit threshold Vt of the inverter 61 of the holding circuit 6 (part (B) of FIG. 3). The output of the inverter 61 is inverted in the inverter 62 and the inverted output is supplied to the input end of the inverter 61. Through this operation, the holding circuit 6 becomes the holding state in which the input end side of the holding circuit 6 becomes the H level and a signal of the L level is output from the output end. Accordingly, the level of the output of the holding circuit 6 does not change at a timing t1 at which the signal level of the first trigger signal is lowered under the circuit threshold Vt of the inverter 61 according to the first time constant τ1. If the output of the holding circuit 6 becomes the L level, a level (part (E) of FIG. 3) of an output signal of the inverter 110 becomes the H level and the NMOS shunt transistor 91 turns on to discharge the ESD surge.

The second trigger circuit 7 outputs a second trigger signal in accordance with the ESD surge ((part C) of FIG. 3). An output signal of the inverter 81 becomes the H level at a timing t2 at which a signal level of the second trigger signal is lowered based on the second time constant τ2, and becomes equal to or less than a circuit threshold Vt of the inverter 81 in the reset circuit 8 (part (D) of FIG. 3). When the output signal of the inverter 81 becomes the H level, the NMOS transistor 82 turns on, a signal of the L level is supplied to the input end of the holding circuit 6, and thus the holding circuit 6 is reset. With this, the output of the holding circuit 6 becomes the H level at the timing t2 (part (B) of FIG. 3) and the output of the inverter 110 becomes the L level (part (E) of FIG. 3). That is, the output signal of the inverter 110 becomes the H level at the timing t0 and becomes the L level at the timing t2 (part (E) of FIG. 3). The NMOS shunt transistor 91 turns on, and discharges the ESD surge for a time when the output signal of the inverter 110 is the H level.

According to the second embodiment, ON of the NMOS shunt transistor 91 may be controlled by using the first time constant τ1 of the first trigger circuit 5. That is, a range of a power source voltage for operating the shunt circuit 9, that is, the fast extent of rising of the power source voltage, for operating the shunt circuit 9 in fluctuation of the power source voltage may be limited by the first time constant τ1. For example, a configuration may be made in which the first time constant τ1 is set to a value in a range from 2 ns to 10 ns which is defined as a rising time of a surge in a human body model (HBM), of the standards of ESD testing, thereby responding to the ESD surge. The first trigger circuit 5 is not operated when the rising time is longer than the first time constant τ1, that is, if the power source voltage fluctuates with a rising time slower than the ESD surge. Thus, a configuration of the electrostatic discharge protection circuit may be made in which the electrostatic discharge protection circuit does not operate when the power source voltage fluctuates to have rising slower than the ESD surge. The timing t2 at which the NMOS shunt transistor 91 turns off may be set by the time constant of the second trigger circuit 7, that is, second time constant τ2. For this reason, a configuration may be made in which the ESD surge may be discharged sufficiently by setting the second time constant τ2 to 1 μs which is a value of six to seven times the time constant of 150 ns defined as the standards of ESD testing. When a negative surge based on the second power source terminal 2 is applied to the first power source terminal 1, a parasitic diode (not illustrated) of the NMOS shunt transistor 91 turns on and discharges the ESD surge.

### Third Embodiment

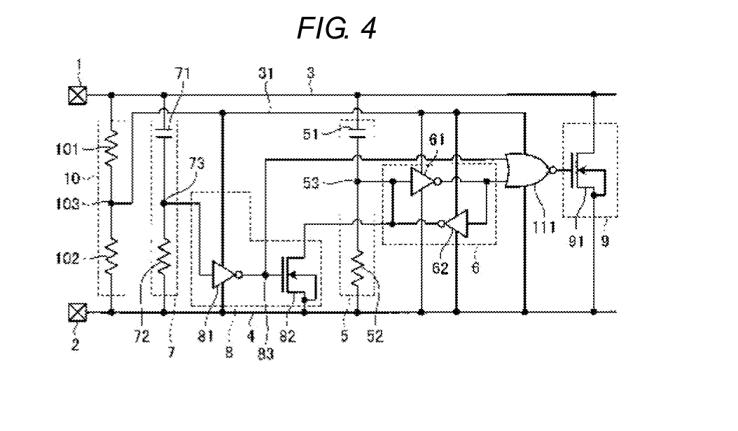

FIG. 4 is a diagram illustrating a configuration of an electrostatic discharge protection circuit according to a third embodiment. Components corresponding to those in the described embodiment are denoted by the same reference numerals and the repetitive descriptions will be made only if necessary. In this third embodiment, a control circuit for controlling the shunt circuit 9 is added. In this third embodiment, the control circuit is configured with a NOR circuit 111. The output signal of the holding circuit 6 is supplied to a first input end of the NOR circuit 111 and the output signal of the inverter 81 of the reset circuit 8 is supplied to a second input end. The NOR circuit 111 is biased by the bias circuit 10. An output signal of the NOR circuit 111 is supplied to the gate electrode of the NMOS shunt transistor 91.

The NOR circuit 111 outputs a signal of the H level when the output signal from the holding circuit 6 and a signal from the inverter 81 in the reset circuit 8 are the L levels together. That is, the NOR circuit 111 outputs the signal of the H level and causes the NMOS shunt transistor 91 to turn on during a time between the timing t0 and the timing t2, similarly to the second embodiment.

In this third embodiment, ON or OFF of the NMOS shunt transistor 91 may be also controlled by setting the time constant τ1 of the first trigger circuit 5 and the time constant τ2 of the second trigger circuit 7. The rising time of the power source voltage for operating the NMOS shunt transistor 91 may be limited by the first time constant τ1 and a time when NMOS shunt transistor 91 is in a state of ON, that is, a discharging time of the electrostatic discharge protection circuit may be controlled by setting the second time constant τ2. A configuration may be made in which the ESD surge is allowed to be sufficiently discharged by increasing the second time constant τ2. Since the range of the power source voltage for operating the electrostatic discharge protection circuit may be limited by the first time constant τ1 even though the second time constant τ2 is large, a configuration for suppressing an incorrect operation may be made.

It is possible to increase controllability of the electrostatic discharge protection circuit by providing a multi-input logical circuit for controlling the NMOS shunt transistor 91. For example, a configuration may be made in which a separately provided control signal is input to the NOR circuit 111, instead of the signal from the inverter 81 configuring the reset circuit 8. For example, a configuration may be made in which a control signal for causing the NMOS shunt transistor 91 to turn off is supplied to the NOR circuit 111.

Additionally, in some embodiments, the NMOS shunt transistor 91 may be replaced with a PMOS transistor. When the conductivity type of the shunt transistor is changed, for example, the NOR circuit 111 is replaced with an OR circuit or the like. In addition, a configuration may be also made in which a connection relationship between the capacitor 51 and the resistor 52 configuring the first trigger circuit 5 or a connection relationship between the capacitor 71 and the resistor 72 configuring the second trigger circuit 7 are replaced. In some embodiments, the NMOS shunt transistor 91 may be replaced with a bipolar transistor. When the bipolar transistor is used, a configuration may be made in which an NPN transistor is used for replacing the NMOS transistor based on a bias relationship.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electrostatic discharge protection circuit comprising:
a first trigger circuit having a first time constant, the first trigger circuit configured to output a first trigger signal in accordance with the first time constant and a voltage applied between a first power source line and a second power source line;
a second trigger circuit having a second time constant that is greater than the first time constant, the second trigger circuit configured to output a second trigger signal in accordance with the second time constant and the voltage applied between the first power source line and the second power source line;
a holding circuit configured to output a shunt control signal in accordance with the first trigger signal and a reset signal;
a reset circuit configured to output the reset signal in accordance with the second trigger signal; and
a shunt circuit connected between the first power source line and the second power source line and configured to provide a conductance path between the first and second power source lines in accordance with the shunt control signal.

2. The electrostatic discharge protection circuit according to claim 1, wherein
the first trigger circuit comprises a first capacitor and a first resistor connected in series; and
the second trigger circuit comprises a second capacitor and a second resistor connected in series.

3. The electrostatic discharge protection circuit according to claim 1, wherein the second time constant is from six to seven times as large as the first time constant.

4. The electrostatic discharge protection circuit according to claim 1, wherein the first time constant is in a range of 2 ns to 10 ns.

5. The electrostatic discharge protection circuit according to claim 1, wherein the shunt circuit comprises a NMOS transistor.

6. The electrostatic discharge protection circuit according to claim 1, wherein the holding circuit comprises:
a first inverter and a second inverter,
the first inverter having a first input that is connected to the first trigger circuit and the reset circuit,
a first output of the first inverter being connected to the shunt circuit and a second input of the second inverter, and
a second output of the second inverter being connected to the first input.

7. The electrostatic discharge protection circuit according to claim 6, wherein the first output and the second input are connected to the shunt circuit via a third inverter.

8. The electrostatic discharge protection circuit according to claim 1, wherein the reset circuit comprises an inverter having an input connected to the second trigger circuit and an output connected to a control electrode of a NMOS transistor having a source connected to the second power source line and a drain connected to the holding circuit.

9. The electrostatic discharge protection circuit according to claim 1, further comprising:
a bias circuit connected between the first and second power source lines and comprising a first resistor element connected in series with a second resistor element, a node between the first resistor element and the second resistor element being connected to a bias voltage line that is connected to the reset circuit and the holding circuit.

10. The electrostatic discharge protection circuit according to claim 1, further comprising:
a NOR circuit configured to receive the shunt control signal at a first NOR input and an inverted second trigger signal at a second NOR input and to output a control signal to the shunt circuit according to a NOR logic operation on the shunt control signal and the inverted second trigger signal.

11. An electrostatic discharge protection circuit comprising:
a first trigger circuit having a first time constant, the first trigger circuit configured to output a first trigger signal in accordance with the first time constant and a voltage applied between a first power source line and a second power source line;
a second trigger circuit having a second time constant that is greater than the first time constant, the second trigger circuit configured to output a second trigger signal in accordance with the second time constant and the voltage applied between the first power source line and the second power source line;
a latch circuit configured to latch the first trigger signal;
a reset circuit configured to reset the latch circuit in accordance with the second trigger signal;
a control circuit configured to output a control signal in accordance with the second trigger signal and an output of the latch circuit; and
a shunt circuit that is connected between the first power source line and the second power source line and configured to provide a conductance path between the first and second power source lines in accordance with the control signal.

12. The electrostatic discharge protection circuit according to claim 11, wherein the control circuit comprises a NOR circuit.

13. The electrostatic discharge protection circuit according to claim 12, wherein the NOR circuit receives the output of the latch circuit and an inverted second control signal as inputs.

14. The electrostatic discharge protection circuit according to claim 11, wherein the shunt circuit comprises a NMOS transistor.

15. The electrostatic discharge protection circuit according to claim 11, wherein the first time constant is in a range of 2 ns to 10 ns.

16. The electrostatic discharge protection circuit according to claim 11, wherein the second time constant is from six to seven times as large as the first time constant.

17. The electrostatic discharge protection circuit according to claim 11, wherein the latch circuit comprises:
a first inverter and a second inverter,
the first inverter having a first input that is connected to the first trigger circuit and the reset circuit,
a first output of the first inverter being connected to the control circuit and a second input of the second inverter, and
a second output of the second inverter being connected to the first input.

18. An electrostatic discharge protection circuit, comprising:
a first trigger circuit including a first capacitor and a first resistor connected in series between a first power source line and a second power source line;
a second trigger circuit including a second capacitor and a second resistor connected in series between the first power source line and the second power source line, the first and second trigger circuit connected in parallel with each other, the second trigger circuit having a time constant that is greater than a time constant of the first trigger circuit;
a first inverter having a first input connected to a node between the second capacitor and the second resistor and a first output connected to a first control electrode of a first NMOS transistor, the first NMOS transistor having a source connected to the second power source line;
a second inverter having a second input connected to a drain of the first NMOS transistor and a node between the first capacitor and the first resistor;
a third inverter having a third input connected to a second output of the second inverter and a third output connected to the second input and the node between the first capacitor and the first resistor; and
a second NMOS transistor having a drain connected to the first power source line and a source connected to the second power source line, a control electrode of the second NMOS transistor receiving a control signal corresponding to a voltage signal at the second output.

19. The electrostatic discharge protection circuit of claim 18, further comprising:
a fourth inverter having a fourth input connected to the second output and a fourth output connected to the control electrode of the second NMOS transistor, wherein
the voltage signal at the second output is inverted by the fourth inverter and then supplied from the fourth output to the control electrode of the second NMOS transistor.

20. The electrostatic discharge protection circuit of claim 18, further comprising:
a NOR circuit having:
a first NOR input connected to the first output,
a second NOR input connected to the second output, and
a NOR output connected to the control electrode of the second NMOS transistor.
